(19) United States
(12) Patent Application Publication
(10) Pub. No.: US 2004/0042272 A1
(43) Pub. Date: Mar. 4, 2004

(54) Novolatile semiconductor memory having multilayer gate structure

(76) Inventor: Minoru Kurata, Tokyo (JP)

Correspondence Address: Finnegan, Henderson, Farabow,, Garrett & Dunner, L.L.P., 1300 I Street, N.W., Washington, DC, 20005-3315, US

(21) Appl. No.: 10/259,431

(22) Filed: Sep. 30, 2002

(30) Foreign Application Priority Data
Aug. 30, 2002 (JP) 2002-254126

(51) Int. Cl. G11C 19/08

(52) U.S. Cl. 365/185.33

(57) ABSTRACT

A semiconductor memory device includes memory cells, source lines, drain lines, and control gate lines. The memory cells are arranged in matrix. Adjacent memory cells in the column direction have one of a source and a drain in common. The sources of memory cells of adjacent two columns are connected to a common source line. The drains of memory cells of adjacent two columns are connected to a common drain line. The drains of memory cells of two columns connected to the source line are connected to different drain lines, respectively. The gates of adjacent memory cells in the row direction are connected to a common control gate line.

### CROSS-REFERENCE TO RELATED APPLICATIONS

This application is based upon and claims the benefit of priority from the prior Japanese Patent Application No. 2002-254126, filed Aug. 30, 2002, the entire contents of which are incorporated herein by reference.

### BACKGROUND OF THE INVENTION

1. Field of the Invention

The present invention relates to a nonvolatile semiconductor memory. More specifically, the invention relates to the structure of a memory cell array and a method of writing and reading data.

2. Description of the Related Art

EEPROMs (electrically erasable and programmable read only memories) are known as nonvolatile semiconductor memories that can write and erase data electrically. Of the EEPROMs, there is a flash memory that can electrically erase a set of data at once.

The structure of a prior art NOR EEPROM will now be described with reference to FIG. 1A. FIG. 1A is a circuit diagram of a memory cell array of the prior art NOR EEPROM.

Referring to FIG. 1A, the memory cell array includes a plurality of memory cells MC arranged in matrix. The control gates of the memory cells MC in the same row are connected to their common one of control gate lines CG1 to CGn (n is a natural number and only CG1 to CG3 are shown in FIG. 1A). Adjacent memory cells in the same column have source and drain regions in common. The drains of the memory cells MC in the same column are connected to their common one of drain lines DL1 to DLm (m is a natural number and only DL1 to DL5 are shown in FIG. 1A). The sources of the memory cells MC in the same row are connected to their common one of source lines SL1 to SLk (k is a natural number and only SL1 is shown in FIG. 1).

FIG. 1B is a plan pattern view of the memory cell array shown in FIG. 1A. As shown in FIG. 1B, the memory cells MC are formed in each of strip-shaped element regions AA electrically isolated by strip-shaped element isolation regions STI. The control gate lines CG1 to CGn extend in a direction perpendicular to the longitudinal direction of the element isolation regions STI. Each of the element regions AA includes a source contact plug SP and a drain contact plug DP that are connected to their respective source and drain of each of the memory cells MC. Drain lines DL1 to DLm (not shown), each of which connects the drain contact plugs DP in each column, extend in the same direction as the longitudinal direction of the element isolation regions STI. The source lines SL1 to SLk (only SL1 is shown in FIG. 1B), each of which connect the source contact plugs SP in each row, extend in a direction parallel to the control gate lines CG1 to CGn.

The following operations of the prior art NOR EEPROM will now be described.

[Erase Operation]

In erase mode, a positive potential Ve of about 10 V is applied to all drain and source lines and a well (semiconductor substrate). A negative potential Vge of about −8 V is applied to all control gate lines. Consequently, electrons are extracted from a floating gate toward a channel. In other words, electrons decrease in the floating gate and positive charges increase seemingly; therefore, the threshold voltage of the memory cells lowers and data is erased from the memory cells.

[Write Operation]

In write mode, the source lines and well are set at a ground potential GND. A potential Vgp of about 8 V and a potential Vdp of about 5 V are applied to their respective control gate line and drain line connected to a selected memory cell. The control gate line and drain line connected to a non-selected memory cell are set at the ground potential GND. Thus, current flows through only the channel of the selected memory cell. Hot electrons generated by the flow of current are injected into the floating gate of the selected memory cell. In other words, electrons increase in the floating gate; therefore, the threshold voltage of the memory cells heightens and data is written to the memory cells.

[Read Operation]

In read mode, the source lines and well are set at the ground potential GND. A potential Vgr of about 5 V and a potential Vdr of about 1 V are applied to their respective control gate line and drain line connected to a selected memory cell. The control gate line and drain line connected to a non-selected memory cell are set at the ground potential GND. In a memory cell in an erase state, current flows into the source from the drain because the threshold voltage of the memory cell is lower than the gate voltage Vgr. In a memory cell in a write state, no current flows because the threshold voltage is higher than the gate voltage Vgr. In other words, data in the memory cells is discriminated depending upon the presence and absence of current.

In the prior art nonvolatile semiconductor memory described above, adjacent memory cells in the same column have a source contact plug and a drain contact plug in common. In other words, one contact plug is formed for each of the memory cells. The area of the occupied memory cells is therefore decreased. Further, the rate of decrease in the area of the memory cell array depends upon not the size of memory cells but the design rule of contact plugs.

However, the prior art nonvolatile semiconductor memory has a large number of contact plugs that restrict the rate of decrease in the area of the memory cell array. The memory cell array is therefore becoming difficult to decrease in size. Furthermore, the contact resistance of the contact plugs is high and the electrical characteristics of the nonvolatile semiconductor memory are likely to deteriorate.

### BRIEF SUMMARY OF THE INVENTION

A semiconductor memory device according to an aspect of the present invention comprises:

memory cells arranged in matrix, adjacent memory cells in a column direction having one of a source and a drain in common;

source lines to each of which sources of memory cells of adjacent two columns are connected;

drain lines to each of which drains of memory cells of adjacent two columns are connected, drains of memory cells of two columns connected to the source line being connected to different drain lines, respectively; and

control gate lines to each of which gates of adjacent memory cells in a row direction are connected.

### BRIEF DESCRIPTION OF THE SEVERAL VIEWS OF THE DRAWING

FIG. 1A is a circuit diagram of a prior art NOR EEPROM;

FIG. 1B is a plan view of the prior art NOR EEPROM;

FIG. 2A is a circuit diagram of a NOR EEPROM according to a first embodiment of the present invention;

FIG. 2B is a plan view of the NOR EEPROM according to the first embodiment of the present invention;

FIG. 2C is a circuit diagram of the NOR EEPROM according to the first embodiment of the present invention;

FIG. 2D is a cross-sectional view taken along line 2D-2D of FIG. 2B;

FIG. 2E is a cross-sectional view taken along line 2E-2E of FIG. 2B;

FIG. 2F is a cross-sectional view taken along line 2F-2F of FIG. 2B;

FIG. 3A is a table showing voltages applied in write mode of the NOR EEPROM according to the first embodiment of the present invention;

FIG. 3B is a table showing voltages applied in read mode of the NOR EEPROM according to the first embodiment of the present invention;

FIG. 4 is a circuit diagram of a NOR EEPROM according to a second embodiment of the present invention;

FIG. 5 is a table showing voltages applied in write mode of the NOR EEPROM according to the second embodiment of the present invention;

FIG. 6A and FIG. 6B are circuit diagrams of part of a memory cell array of the NOR EEPROM according to the second embodiment of the present invention, which is shown to describe a write operation of the EEPROM;

FIG. 7 is a table showing voltages applied in read mode of the NOR EEPROM according to the second embodiment of the present invention;

FIG. 8A and FIG. 8B are circuit diagrams of part of a memory cell array of the NOR EEPROM according to the second embodiment of the present invention, which is shown to describe a read operation of the EEPROM;

FIG. 9A is a plan view of a NOR EEPROM according to a first modification to the first and second embodiments of the present invention;

FIG. 9B is a cross-sectional view taken along line 9B-9B of FIG. 9A;

FIG. 10A is a plan view of a NOR EEPROM according to a second modification to the first and second embodiments of the present invention;

FIG. 10B is a cross-sectional view taken along line 10B-10B of FIG. 10A; and

FIG. 11 is a plan view of a NOR EEPROM according to a third modification to the first and second embodiments of the present invention.

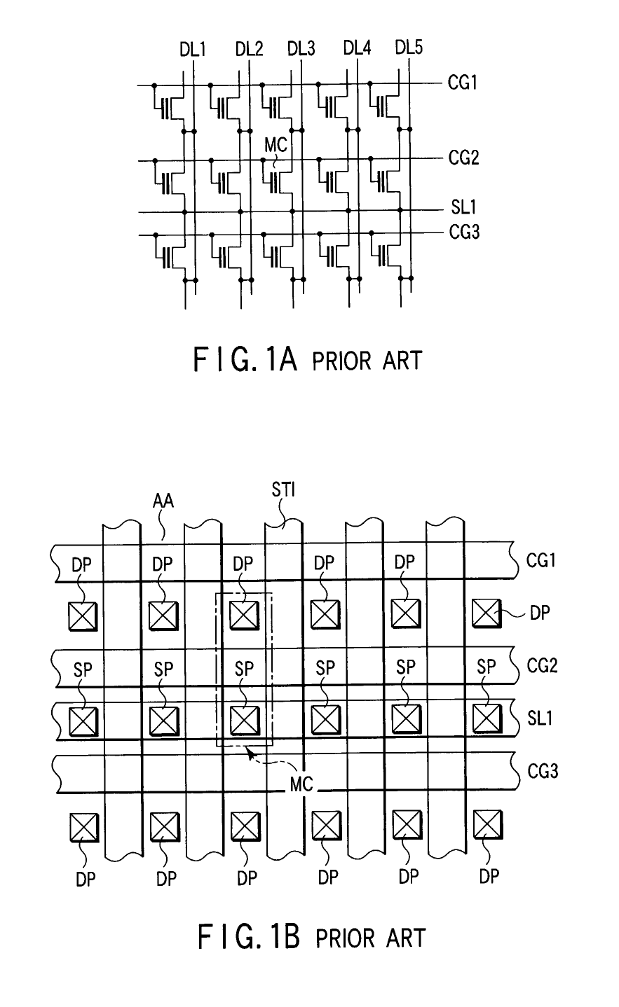

### DETAILED DESCRIPTION OF THE INVENTION

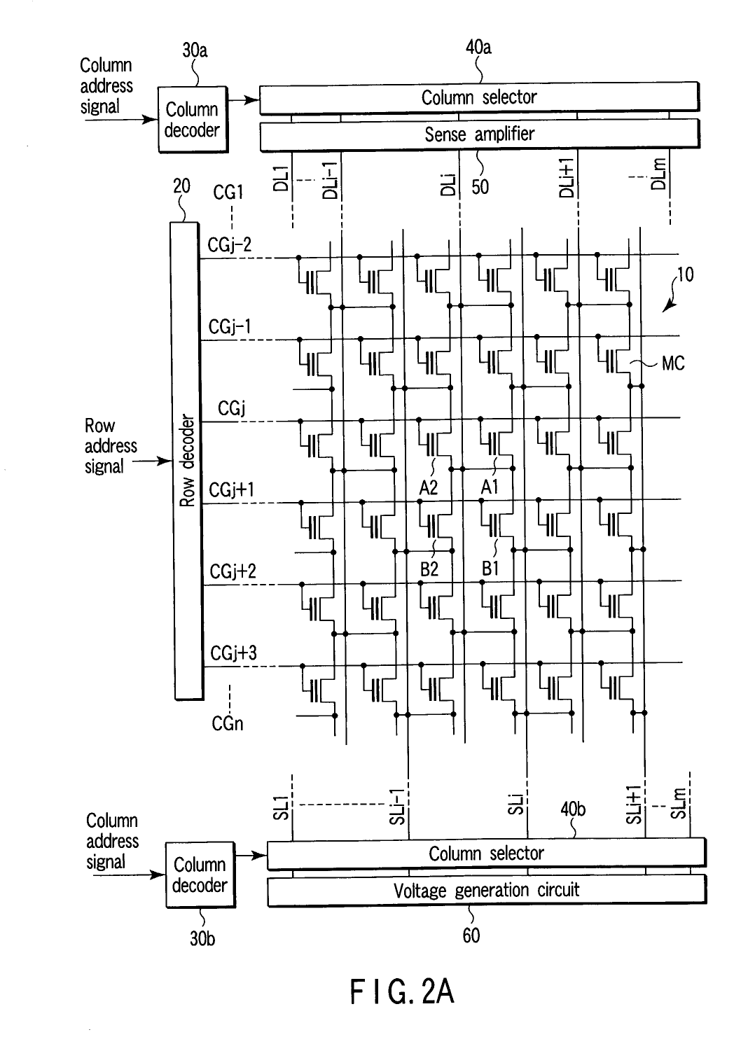

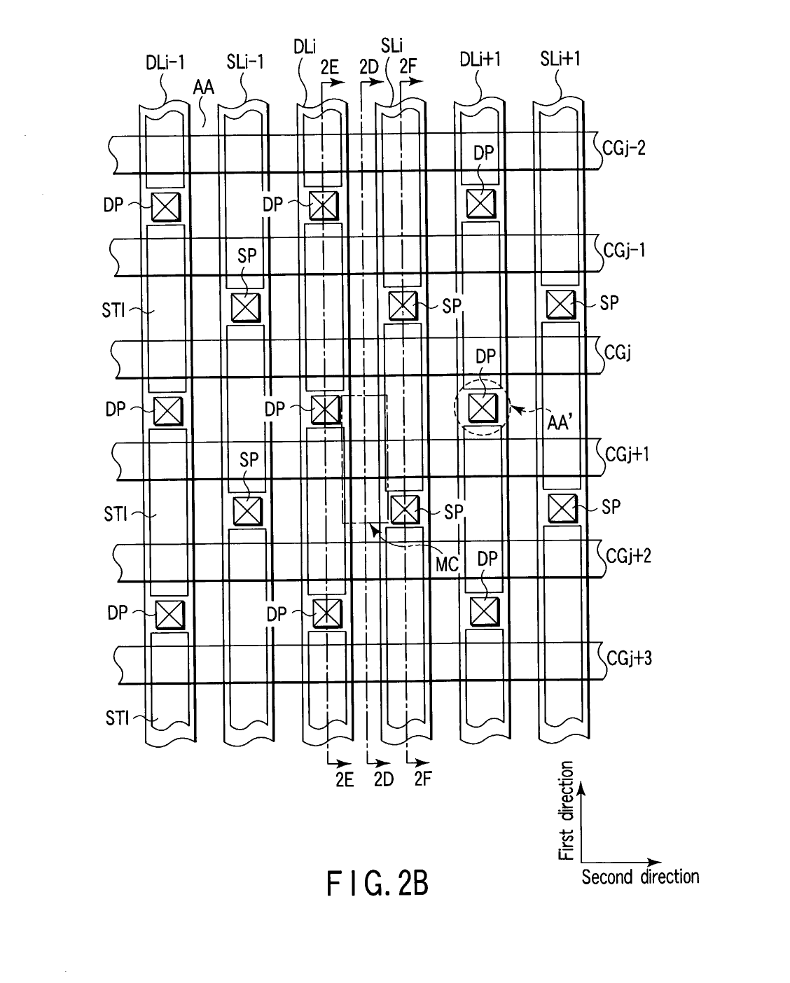

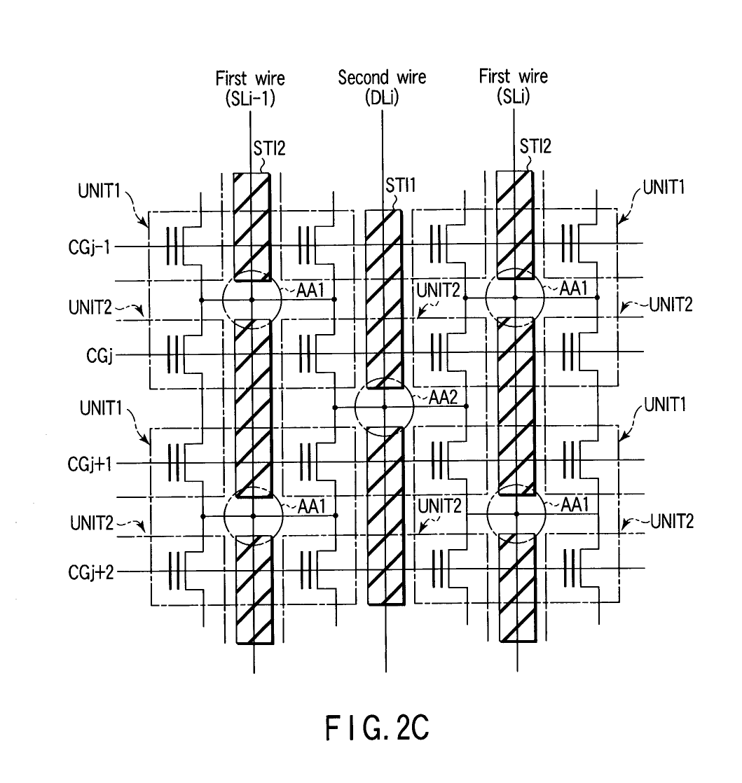

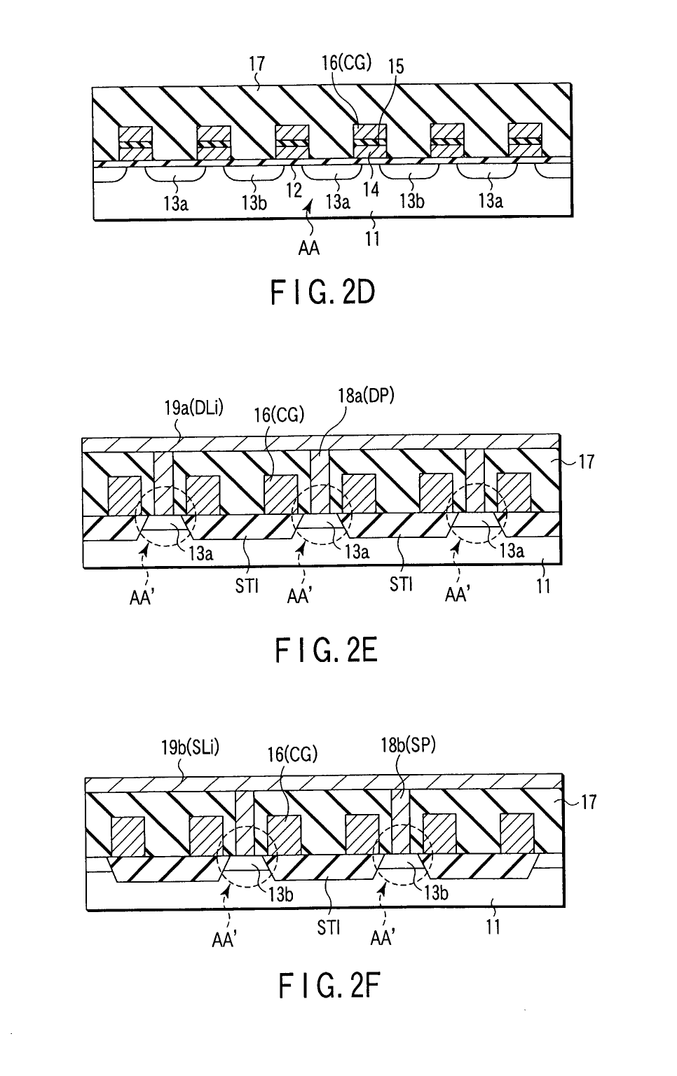

A nonvolatile semiconductor memory according to a first embodiment of the present invention will now be described with reference to FIG. 2A, taking an EEPROM as an example. FIG. 2A is a circuit diagram of a NOR EEPROM according to the first embodiment.

As shown in FIG. 2A, the NOR EEPROM comprises a memory cell array 10, a row decoder 20, column decoders 30a and 30b, column selectors 40a and 40b, a sense amplifier 50, and a voltage generation circuit 60.

The memory cell array 10 includes a plurality of memory cells MC arranged in matrix. The memory cells MC are each configured by a MOS transistor including a multilayer gate having, e.g., a control gate and a floating gate. The control gates of memory cells MC arranged in the same row are connected to a common control gate line CGj (j=1 to n, j and n are each natural number). Adjacent memory cells MC in the same column have one of source and drain regions in common. The drains of memory cells MC of adjacent two columns are connected to a common drain line DLi (i=1 to m, i and m are each natural number). The sources of memory cells MC of adjacent two columns are connected to a common source line SLi. However, the memory cells MC of adjacent two columns have only one of source and drain lines in common.

The row decoder 20 decodes an externally input row address signal. In response to the row address signal, the row decoder applies a given voltage to the control gate lines CG1 to CGn.

The column decoders 30a and 30b decode an externally input column address signal. In response to the column address signal, the column decoders 30a and 30b control column selectors 40a and 40b, respectively.

The column selector 40a selects one from among the drain lines DL1 to DLm in response to the decoded column address signal. The column selector 40b selects one from among the source lines SL1 to SLm in response to the decoded column address signal.

In write mode, the sense amplifier 50 latches write data. In read mode, the sense amplifier 50 latches data read out of a memory cell MC.

The voltage generation circuit generates a voltage and applies it to any one of the source lines SL1 to SLm selected by the column selector 40b.

The configuration of the memory cell array described above will now be described in detail. FIG. 2B is a plan pattern view of part of the memory cell array shown in FIG. 2A. In this pattern view, first and second directions are defined as indicated by arrows in FIG. 2B.

Referring to FIG. 2B, a plurality of element isolation regions STI in strip-shape along the first direction is formed in a semiconductor substrate at regular intervals along the second direction perpendicular to the first direction. An element region AA is formed between adjacent element isolation regions STI and memory cells are formed in the element region AA. A plurality of control lines CG1 to CGn in strip-shape along the second direction is formed at regular intervals along the first direction. A source region and a drain region are formed in the element region AA so as to sandwich a control gate line, thus forming a memory cell MC. As described above, adjacent memory cells in the same column have one of the source and drain regions in common. The element isolation regions STI are each partly removed. In other words, each of the element isolation regions STI is separated into regions in the first direction with a space between adjacent regions. The regions are each located directly under two control gate lines and between the two control gates. The space is located between the control gates on one and another region respectively. The space is an element region AA′. An impurity diffusion layer is formed in the element region AA′. Sources or drains of the memory cells MC of adjacent two columns in the second direction are connected to each other by the element region AA′. Consequently, the element regions AA′ are used as source and drain regions alternately in the second direction. In other words, the element regions AA′ are arranged in a staggered format, as are the element isolation regions STI.

The configuration of the memory cell array can be rephrased as follows. The element isolation regions STI whose longitudinal direction is equal to the first direction are arranged in a staggered format. The control gate lines CG1 to CGn are formed in the second direction. Two control gate lines pass across each of the element isolation regions STI. The control gate line CGj alternately passes across the same element isolation regions STI as those across which the control gate lines CGj+1 and CGj−1 pass. The element region AA′ is interposed between adjacent element isolation regions STI in the first direction. This element region AA′ is also interposed between adjacent control gate lines.

Either a source contact plug SP or a drain contact plug DP is formed in the element region AA′. The source contact plugs SP in the same column are connected to their common one of the source lines SL1 to SLm. The drain contact plugs DP in the same column are connected to their common one of the drain lines DL1 to DLm. The source lines SL1 to SLm and drain lines DL1 to DLm are formed in the first direction and shaped like a strip. These source and drain lines overlap the element isolation regions STI. The source contact plugs SP and drain contact plugs DP are arranged alternately in the second direction as described above, as are the source lines SL1 to SLm and drain lines DL1 to DLm.

The configuration of the above memory cell array can be described with reference to FIG. 2C. FIG. 2C is a circuit diagram of the memory cell array of the NOR EEPROM shown in FIGS. 2A and 2B.

Referring to FIG. 2C, the memory cell array includes a plurality of first memory cell units UNIT1 arranged in matrix. Each of the first memory cell units UNIT1 includes four memory cells MC arranged in matrix. Ends (sources) of current paths of the four memory cells are connected to one another. The closest four memory cells MC of adjacent four first memory cell units UNIT1 compose a second memory cell unit UNIT2. The memory cells MC belong to one of the second memory cell units UNIT2 as well as one of the first memory cell units UNIT1. The four memory cells MC of each of the first memory cell units UNIT1 belong to their respective second memory cell units UNIT2. Needless to say, the four memory cells MC of each of the second memory cell units UNIT2 belong to their respective first memory cell units UNIT1. The other ends (drains) of the current paths of the four memory cells MC of the second memory cell unit UNIT2 are connected to one another. The ends (sources) of the current paths of the first memory cell units UNIT1 in the same column are connected to a common first wire (source line). The other ends (drains) of the current paths of the second memory cell units UNIT2 in the same column are connected to a common second wire (drain line). Furthermore, the gates of the memory cells in the same row are connected to a common control gate line.

A first element isolation region STI1 is formed between adjacent first memory cell units UNIT1 in the row direction to electrically isolate these units UNIT1 from each other. A second element isolation region STI2 is formed between adjacent second memory cell units UNIT2 in the row direction to electrically isolate these units UNIT2 from each other. A region AA1 is formed between adjacent second element isolation regions STI2 in the column direction, and a contact plug (source contact plug SP) that connects a common end of the current paths in the first memory cell unit UNIT1 to the first wire is formed in the region AA1. On the other hand, a region AA2 is formed between adjacent first element isolation regions STI1 in the column direction, and a contact plug (drain contact plug DP) that connects the other common end of the current paths in the second memory cell unit UNIT2 to the second wire is formed in the region AA2. These regions AA1 and AA2 correspond to the region AA′ shown in FIG. 2B.

The section of the memory cell array will now be described with reference to FIGS. 2D to 2F. FIGS. 2D to 2F are cross-sectional views taken along lines 2D-2D, 2E-2E and 2F-2F of FIG. 2B, respectively.

First, the configuration of the memory cell array will be described with reference to FIG. 2D showing the cross-sectional view taken along line 2D-2D in the element region AA. As shown in FIG. 2D, a plurality of impurity diffusion layers 13a and 13b is formed in a surface area of a semiconductor substrate (silicon substrate) 11. The impurity diffusion layer 13a serves as a drain region and the impurity diffusion layer 13b serves as a source region. A floating gate electrode 14 is formed on the semiconductor substrate 11 with a gate insulation film interposed therebetween. The gate insulation film 12 is made of, for example, silicon oxide and oxynitride. The floating gate electrode 14 is made of, for example, polysilicon. A control gate electrode 16 is formed on the floating gate electrode 14 with a gate-to-gate insulation film 15 interposed therebetween such that the electrode 16 covers the electrode 14. The gate-to-gate insulation film 15 is formed of a three-layer ONO film of silicon oxide, silicon nitride and silicon oxide, a single-layer film of silicon oxide, a two-layer ON film of silicon oxide and silicon nitride, a two-layer NO film or the like. A multilayer gate containing the floating gate electrode 14 and control gate electrode 16 and the source and drain regions 13b and 13a make up a memory cell (flash cell) MC. Furthermore, an interlayer insulation film 17 is formed on the semiconductor substrate 11 so as to coat the memory cell MC.

Then, the configuration of the memory cell array will be described with reference to FIG. 2E showing the cross-sectional view taken along line 2E-2E. As shown in FIG. 2E, the semiconductor substrate includes a plurality of element isolation regions STI. Not the floating gates 14 but the control gate electrodes 16 are formed on each of the element isolation regions STI. Each of the element isolation regions STI is formed across a region directly under two control gate electrodes 16. The element isolation regions STI are arranged so as to sandwich a region (element region AA′) formed between adjacent two control gate electrodes 16. The drain region 13a is formed in the element region AA′ and connected to the drain region 13a in the element region AA. The interlayer insulation film 17 is formed on the semiconductor substrate 11 so as to coat the control gate electrode 16. Moreover, drain contact plugs 18a are formed in the interlayer insulation film 17 so as to be connected to their corresponding drain regions 13a. A metal wiring layer 19a is formed on the interlayer insulation film 17 to connect the drain contact plugs 18a in common. The metal wiring layer 19a functions as a drain line DLi.

Then, the configuration of the memory cell array will be described with reference to FIG. 2F showing the cross-sectional view taken along line 2F-2F. As is apparent from FIG. 2F, the configuration is basically the same as that of the memory cell array shown in FIG. 2E. The positions of element regions AA′ are each shifted by half cycle from those of element regions AA′ in the configuration shown in FIG. 2E. More specifically, the element region AA′ is formed adjacent to a region in which the source region 13b is to be formed in the configuration shown in FIG. 2D. The source region 13b is formed in the element region AA′ and connected to the source region 13b in the element region AA. Source contact plugs 18b are formed in the interlayer insulation film 17 so as to be connected to their corresponding source regions 13b. A metal wiring layer 19b is formed on the interlayer insulation film 17 to connect the source contact plugs 18b in common. The metal wiring layer 19b functions as a source line SLi.

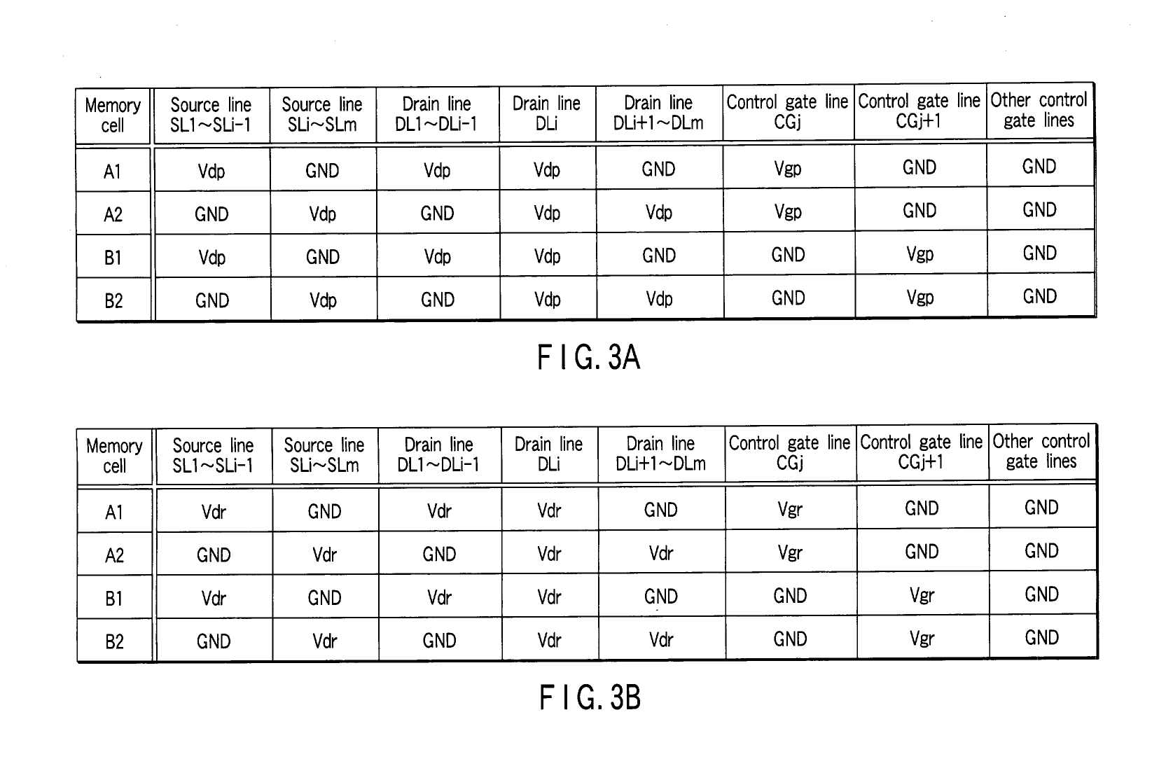

An operation of the NOR EEPROM according to the first embodiment will now be described with reference to FIGS. 2A, 3A and 3B. FIG. 3A is a table showing voltages applied in write mode of the NOR EEPROM and FIG. 3B is a table showing voltages applied in read mode thereof. In FIGS. 3A and 3B, cell A1 corresponds to a memory cell MC whose gate is connected to the control gate line CGj, drain is connected to the drain line DLi, and source is connected to the source line SLi, as shown in FIG. 2A. Cell A2 corresponds to a memory cell MC whose gate is connected to the control gate line CGj, drain is connected to the drain line DLi, and source is connected to the source line SLi−1. Cell B1 corresponds to a memory cell MC whose gate is connected to the control gate line CGj+1, drain is connected to the drain line DLi, and source is connected to the source line SLi. Cell B2 corresponds to a memory cell MC whose gate is connected to the control gate line CGj+1, drain is connected to the drain line DLi, and source is connected to the source line SLi−1.

[Write Operation]

The write operation of the NOR EEPROM will be described with reference to FIGS. 2A and 3A, taking an operation of writing data to cell A1 as an example.

First, the semiconductor substrate (well region) 11 is set at a ground potential GND. The voltage generation circuit 60 applies a potential Vdp to the source lines SL1 to SLi−1 and sets the source lines SLi to SLm at the ground potential GND. The drain lines DL1 to DLi are set at the potential Vdp through the sense amplifier 50 and drain lines DLi+1 to DLm are set at the ground potential GND. The potential Vdp is, for example, about 5 V. The row decoder 20 applies a potential Vgp to the control gate line CGj and sets the other control gate lines CG1 to CGj−1 and CGj+1 to CGn at the ground potential GND. The potential Vgp is, for example, about 8 V. In the cell A1, therefore, the potential Vgp is applied to the control gate and the potential difference Vdp is applied between the source and drain. Consequently, current flows through a channel region between the source and drain to generate hot electrons. The hot electrons are injected into the floating gate of the cell A1. Thus, the number of electrons in the floating gate of the cell A1 increase and so does the threshold voltage of the cell A1. In other words, data is written to the cell A1.

The status of the cell A2 appearing when data is written to the cell A1 will now be described. Since the control gate of the cell A2 is connected to the same control gate line CGj as that of the cell A1, its potential is Vgp. However, the potentials of the source line SLi−1 and drain line DLi connected to the source and drain of the cell A2 are both Vdp. In other words, there is no difference in potential between the source and drain of the cell A2. No current flows between the source and drain or no hot electrons are generated. Consequently, no electrons are injected into the floating gate of the cell A2 and, in other words, no data is written to the cell A2.

Then, the status of the cell B1 will be described. The source and drain of the cell B1 are connected to the source line SLi and drain line DLi, respectively, like the source and drain of the cell A1. There is a potential difference Vdp between the source and drain of the cell B1. However, the control gate of the cell B1 is connected to the control gate line CGj+1 other than the control gate line CGj to which the control gate of the cell A1 is connected. The control gate line CGj+1 is set at the ground potential GND. Therefore, no electrons are injected into the floating gate and, in other words, no data is written to the cell B1.

As for the cell B2, there is no difference in potential between the source and drain and the control gate is set at the ground potential GND. Thus, no data is written to the cell B2, either.

As described above, data is written to only the cell A1.

An operation of writing data to the cell A2 will now be described. First, the semiconductor substrate (well region) 11 is set at the ground potential GND. The voltage generation circuit 60 sets the source lines SL1 to SLi−1 at the ground potential GND and applies the potential Vdp to the source lines SLi to SLm. The drain lines DL1 to DLi−1 are set at the ground potential GND and the potential Vdp is applied to the drain lines DLi to DLm through the sense amplifier 50. The row decoder 20 applies the potential Vgp to the control gate line CGj and sets the other control gate lines CG1 to CGj−1 and CGj+1 to CGn at the ground potential GND. In the cell A2, therefore, the potential Vgp is applied to the control gate and the potential difference Vdp is applied between the source and drain. Thus, data is written to the cell A2.

The status of the cell A1 appearing when data is written to the cell A2 will now be described. The potential Vgp is applied to the control gate of the cell A1 like the control gate of the cell A2. However, the potentials of the source line SLi and drain line DLi connected to the source and drain of the cell A1 are both Vdp. In other words, there is no difference in potential between the source and drain of the cell A1. No data is therefore written to the cell A1.

As for the cell B1, there is no difference in potential between the source and drain and the control gate is set at the ground potential GND. Thus, no data is written to the cell B1, either.

The status of the cell B2 will be described. There is a difference in potential between the source and drain of the cell B2. However, the control gate of the cell B2 is connected to the control gate line CGj+1 set at the ground potential GND. Data is not therefore written to the cell B2.

As described above, data is written to only the cell A2.

In order to write data to the cell B1, the potential Vgp has only to be applied to only the control gate line CGj+1 and the other control gate lines CG1 to CGj and CGj+2 to CGn have only to be set at the ground potential GND when data is written to the cell A1. Thus, data is written to only the cell B1 as described above with respect to the write of data to the cell A1.

In order to write data to the cell B2, the potential Vgp has only to be applied to only the control gate line CGj+1 and the other control gate lines CG1 to CGj and CGj+2 to CGn have only to be set at the ground potential GND when data is written to the cell A2. Thus, data is written to only the cell B2 as described above with respect to the write of data to the cell A2.

[Read Operation]

The read operation of the NOR EEPROM will be described with reference to FIGS. 2A and 3B, taking an operation of reading data from cell A1 as an example.

First, the semiconductor substrate (well region) 11 is set at a ground potential GND. The voltage generation circuit 60 applies a potential Vdr to the source lines SL1 to SLi−1 and sets the source lines SLi to SLm at the ground potential GND. The potential Vdr is applied to the drain lines DL1 to DLi through the sense amplifier and the drain lines DLi+1 to DLm are set at the ground potential GND. The potential Vdr is, for example, about IV. The row decoder 20 applies a potential Vgr to the control gate line CGj and sets the other control gate lines CG1 to CGj−1 and CGj+1 to CGn at the ground potential GND. The potential Vgr is, for example, about 5 V. In the cell A1, therefore, the potential Vgr is applied to the control gate and the potential difference Vdr is applied between the source and drain. If data is written to the cell A1, the threshold voltage of the cell A1 is higher than the gate voltage Vgr; therefore, the cell A1 turns off to prevent current from flowing between the source and drain of the cell A1. If the cell A1 is in an erase state, the threshold voltage of the cell A1 is lower than the gate voltage Vgr; therefore, the cell A1 turns on to cause current to flow between the source and drain of the cell A1. Data can thus be read out of the cell A1 according to whether current is present or absent in the drain line DLi of the cell A1 (whether the potential of the drain line DLi varies or not).

The descriptions of the status of the other cells when data is read out of the cell A1 are omitted. As in the write operation, no data is read out of the other cells (non-selected memory cells), because there is no difference in potential between the source and drain or the control gate is set at the ground potential.

An operation of reading data from the cell A2 will now be described. First, the semiconductor substrate (well region) 11 is set at the ground potential GND. The voltage generation circuit 60 sets the source lines SL1 to SLi−1 at the ground potential GND and applies the potential Vdr to the source lines SLi to SLm. The drain lines DL1 to Dli−1 are set at the ground potential GND and the potential Vdr is applied to the drain lines DLi to DLm through the sense amplifier 50. The row decoder 20 applies the potential Vgr to the control gate line CGj and sets the other control gate lines CG1 to CGj−1 and CGj+1 to CGn at the ground potential GND. In the cell A2, therefore, the potential Vgr is applied to the control gate and the potential difference Vdr is applied between the source and drain. Thus, data is read out of the cell A2.

In order to read data from the cell B1, the potential Vgr has only to be applied to only the control gate line CGj+1 and the other control gate lines CG1 to CGj and CGj+2 to CGn have only to be set at the ground potential GND when data is read out of the cell A1. Thus, data is read from only the cell B1 as in the operation of reading data from the cell A1.

In order to read data from the cell B2, the potential Vgr has only to be applied to only the control gate line CGj+1 and the other control gate lines CG1 to CGj and CGj+2 to CGn have only to be set at the ground potential GND when data is read out of the cell A2. Thus, data is read from only the cell B2 as in the operation of reading data from the cell A2.

[Erase Operation]

The erase operation of the NOR EEPROM according to the first embodiment is similar to that of the prior art EEPROM. A positive potential of about 10 V is applied to all the drain lines DL1 to DLm and all the source lines SL1 to SLm. A negative potential of about −8 V is applied to all the control gate lines CG1 to CGn. Consequently, electrons are extracted from the floating gates of all the memory cells MC toward the semiconductor substrate and data is erased from the memory cells MC.

In the foregoing NOR EEPROM according to the first embodiment of the present invention, the drains of memory cells in adjacent two columns are connected to a common drain line and the sources of memory cells in adjacent two columns are connected to a common source line. The sources of memory cells of two columns, whose drains are connected to a common drain line DLi, are connected to source lines SLi and SLi−1. The drains of memory cells of two columns, whose sources are connected to a common source line SLi, are connected to drain lines DLi and DLi+1. Thus, the sources or drains of adjacent four memory cells are connected to each other. The number of source contact plugs and that of drain contact plugs each can be reduced by half, though conventionally two memory cells required one source contact plug and one drain contact plug. The contact plugs, which interfered with microfabrication, can be reduced in number and thus the NOR EEPROM can be increased in packing density further. If the contact plugs are decreased in number, the cross-sectional area of the contact plug can be made larger than that of the prior art EEPROM. Consequently, the contact resistance at the contact plug can be lowered and accordingly the electrical characteristics of the NOR EEPROM can be improved.

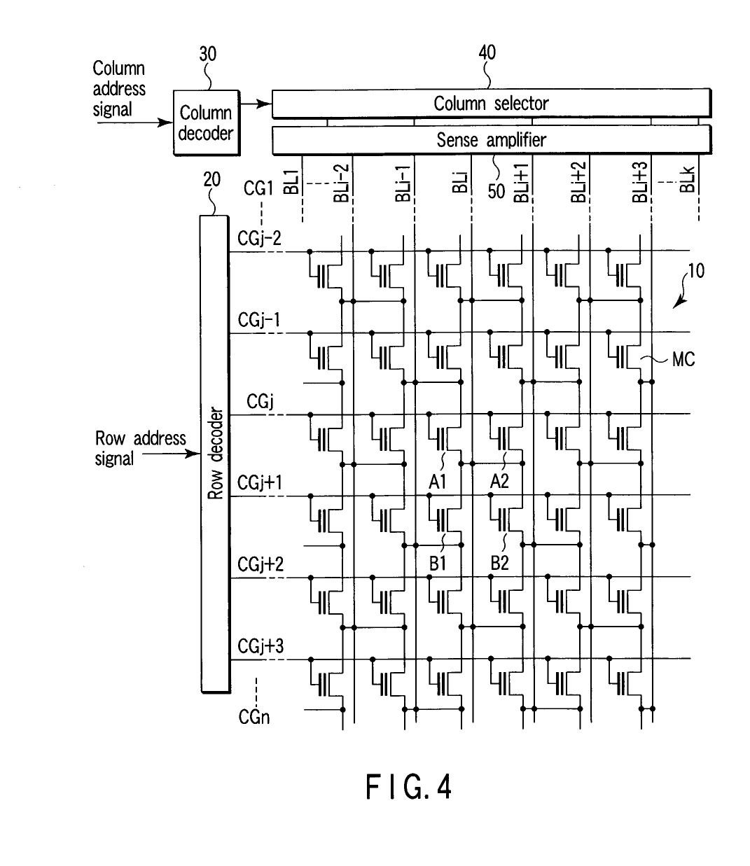

A nonvolatile semiconductor memory according to a second embodiment of the present invention will now be described with reference to FIG. 4, taking an EEPROM as an example. FIG. 4 is a circuit diagram of a NOR EEPROM according to the second embodiment.

As shown in FIG. 4, the source and drain lines of the first embodiment are replaced with bit lines BL1 to BLk. Furthermore, the column decoders 30a and 30b of the first embodiment are replaced with one column decoder 30 and the column selectors 40a and 40b thereof are replaced with one column selector 40.

A memory cell array 10 includes a plurality of memory cells MC arranged in matrix. The control gates of memory cells MC arranged in the same row are connected to a common control gate line CGj (j=1 to n, j and n are each natural number). Adjacent memory cells MC in the same column have one of impurity diffusion layers, which serve as source and drain regions, in common. One impurity diffusion layer of the memory cells MC in one column and that of memory cells MC in one adjacent column are connected to a common bit line BLi (i=1 to k, i and k are each natural number). The other impurity diffusion layer of the memory cells MC in the one column and that of memory cells MC in the other adjacent column are connected to a common bit line BLi+1 (or BLi−1).

The row decoder 20 decodes an externally input row address signal. In response to the row address signal, the row decoder applies a given voltage to the control gate lines CG1 to CGn.

The column decoder 30 decodes an externally input column address signal. In response to the column address signal, the column decoder 30 controls the column selector 40.

The column selector 40 selects one from among the bit lines BL1 to BLk in response to the decoded column address signal.

In write mode, a sense amplifier 50 latches write data. In read mode, the sense amplifier 50 latches data read out of a memory cell MC.

Since the plan and sectional views of the memory cell array 10 are the same as those shown in FIGS. 2B to 2F, the descriptions of the configuration of the memory cell array are omitted. In the second embodiment, however, each of the impurity diffusion layers 13a and 13b serves as either of source and drain. Accordingly, the drain contact plug 18a and source contact plug 18b both serve as bit line contact plugs connected to the bit lines BL1 to BLk.

An operation of the NOR EEPROM according to the second embodiment will now be described. As shown in FIG. 4, a memory cell MC whose gate is connected to the control gate line CGj and source-to-drain current path is connected between the bit lines BLi−1 and BLi is defined as cell A1. A memory cell MC whose gate is connected to the control gate line CGj and source-to-drain current path is connected between the bit lines BLi and BLi+1 is defined as cell A2. A memory cell MC whose gate is connected to the control gate line CGj+1 and source-to-drain current path is connected between the bit lines BLi−1 and BLi is defined as cell B1. A memory cell MC whose gate is connected to the control gate line CGj+1 and source-to-drain current path is connected between the bit lines BLi and BLi+1 is defined as cell B2.

[Write Operation]

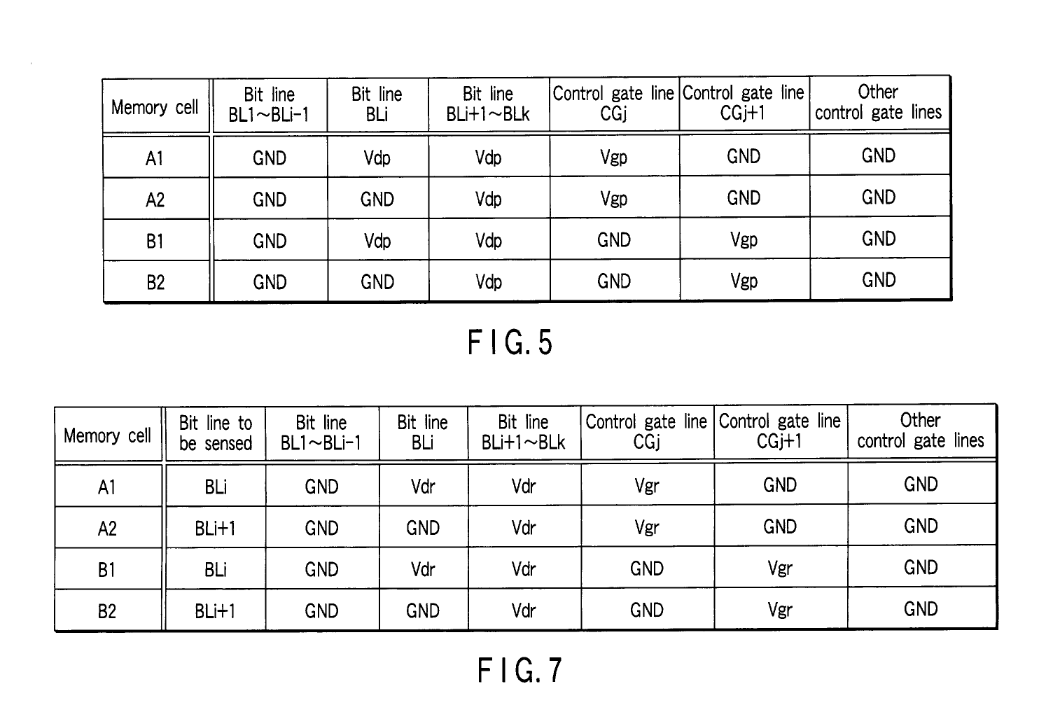

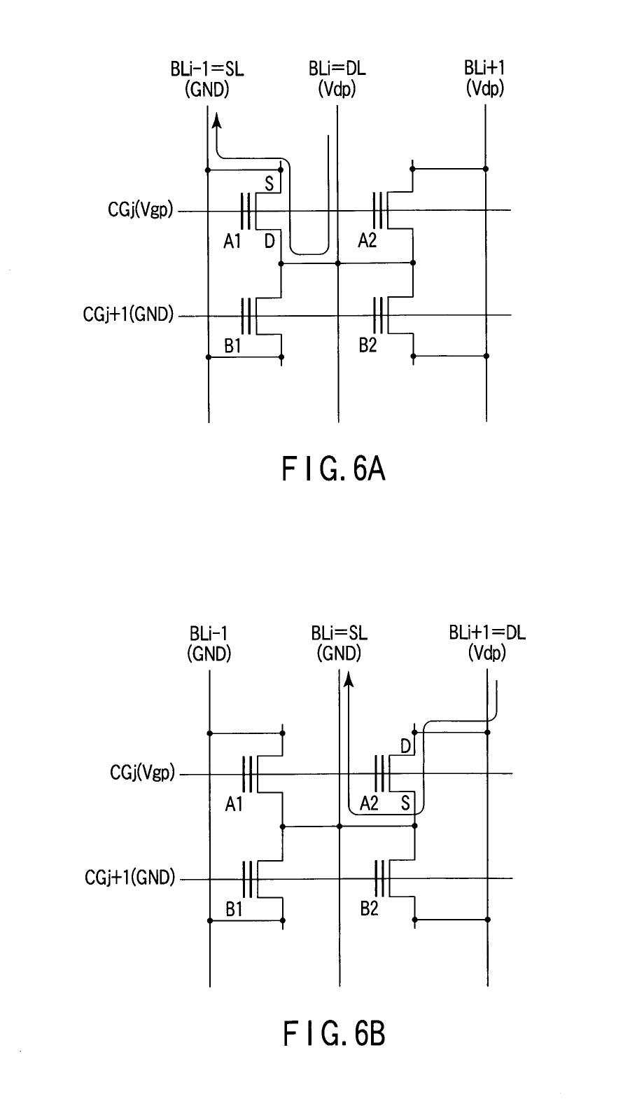

The write operation of the NOR EEPROM according to the second embodiment will be described with reference to FIGS. 5 and 6A, taking an operation of writing data to the cell A1 as an example. FIG. 5 is a table showing voltages applied in the write operation of the NOR EEPROM. FIG. 6A is an enlarged circuit diagram of part of the NOR EEPROM shown in FIG. 4.

First, the semiconductor substrate (well region) is set at a ground potential GND. The bit lines BL1 to BLi−1 are set at the ground potential GND and a potential Vdp is applied to the bit lines BLi to BLk through the sense amplifier. The row decoder 20 applies a potential Vgp to the control gate line CGj and sets the other control gate lines CG1 to CGj−1 and CGj+1 to CGn at the ground potential GND. As shown in FIG. 6A, the bit line BLi−1 functions as a source line and the bit line BLi functions as a drain line. Paying attention to the cell A1, the impurity diffusion layer connected to the bit line BLi−1 serves as a source region and the impurity diffusion layer connected to the bit line BLi serves as a drain region. A potential difference Vdp is applied between the source and drain of the cell A1. Current (indicated by the arrow in FIG. 6A) flows through a channel region between the source and drain of the cell A1 and consequently data is written to the cell A1.

As for the other memory cells MC, there is no difference in potential between the source and drain, or no potential is applied to the control gate line CG; therefore, no data is written to the other memory cells MC.

An operation of writing data to the cell A2 will now be described with reference to FIGS. 5 and 6B. FIG. 6B is an enlarged circuit diagram of part of the NOR EEPROM shown in FIG. 4.

First, the semiconductor substrate (well region) is set at a ground potential GND. The bit lines BL1 to BLi−1 are set at the ground potential GND and a potential Vdp is applied to the bit lines BLi+1 to BLk through the sense amplifier. The row decoder 20 applies a potential Vgp to the control gate line CGj and sets the other control gate lines CG1 to CGj−1 and CGj+1 to CGn at the ground potential GND. As shown in FIG. 6B, the bit line BLi functions as a source line and the bit line BLi+1 functions as a drain line. Paying attention to the cell A2, the impurity diffusion layer connected to the bit line BLi serves as a source region and the impurity diffusion layer connected to the bit line BLi+1 serves as a drain region. A potential difference Vdp is applied between the source and drain of the cell A2. Current (indicated by the arrow in FIG. 6B) flows through a channel region between the source and drain of the cell A2 and consequently data is written to the cell A2.

As for the other memory cells MC, there is no difference in potential between the source and drain, or no potential is applied to the control gate line CG; therefore, no data is written to the other memory cells MC.

In order to write data to the cell B1, the potential Vgp has only to be applied to only the control gate line CGj+1 and the other control gate lines CG1 to CGj and CGj+2 to CGn have only to be set at the ground potential GND when data is written to the cell A1. Thus, data is written to only the cell B1 as described above with respect to the write of data to the cell A1. In this case, the bit line BLi−1 serves as a source line and the bit line BLi serves as a drain line as in the operation of writing data to the cell A1.

In order to write data to the cell B2, the potential Vgp has only to be applied to only the control gate line CGj+1 and the other control gate lines CG1 to CGj and CGj+2 to CGn have only to be set at the ground potential GND when data is written to the cell A2. Thus, data is written to only the cell B2 as described above with respect to the write of data to the cell A2. In this case, the bit line BLi−1 serves as a source line and the bit line BLi serves as a drain line as in the operation of writing data to the cell A2.

[Read Operation]

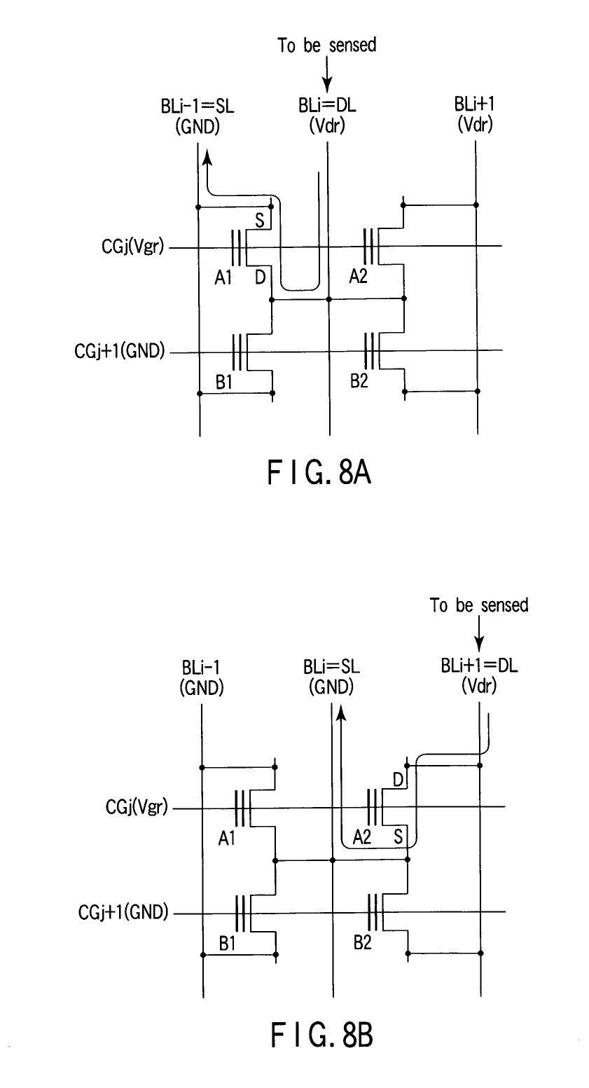

The read operation of the NOR EEPROM according to the second embodiment will be described with reference to FIGS. 7 and 8A, taking an operation of reading data from the cell A1 as an example. FIG. 7 is a table showing voltages applied in the read operation of the NOR EEPROM. FIG. 8A is an enlarged circuit diagram of part of the NOR EEPROM shown in FIG. 4.

First, the semiconductor substrate (well region) is set at a ground potential GND. The bit lines BL1 to BLi−1 are set at the ground potential GND and a potential Vdr is applied to the bit lines BLi to BLk through the sense amplifier. The row decoder 20 applies a potential Vgr to the control gate line CGj and sets the other control gate lines CG1 to CGj−1 and CGj+1 to CGn at the ground potential GND. As shown in FIG. 8A, the bit line BLi−1 functions as a source line and the bit line BLi functions as a drain line. Paying attention to the cell A1, the impurity diffusion layer connected to the bit line BLi−1 serves as a source region and the impurity diffusion layer connected to the bit line BLi serves as a drain region. A potential difference Vdr is applied between the source and drain of the cell A1. If data is written to the cell A1, the cell A1 turns off and no current flows between the source and drain of the cell A1. If the cell A1 is in an erase state, it turns on and current flows between the source and drain of the cell A1. The sense amplifier senses whether current is present or absent in the bit line BLi (whether the potential of the bit line BLi varies or not), thereby reading data from the cell A1.

An operation of reading data from the cell A2 will now be described with reference to FIGS. 7 and 8B. FIG. 8B is an enlarged circuit diagram of part of the NOR EEPROM shown in FIG. 4.

First, the semiconductor substrate (well region) 11 is set at a ground potential GND. The bit lines BL1 to BLi are set at the ground potential GND and a potential Vdr is applied to the bit lines BLi+1 to BLk through the sense amplifier. The row decoder 20 applies a potential Vgr to the control gate line CGj and sets the other control gate lines CG1 to CGj−1 and CGj+1 to CGn at the ground potential GND. As shown in FIG. 8B, the bit line BLi functions as a source line and the bit line BLi+1 functions as a drain line. Paying attention to the cell A2, the impurity diffusion layer connected to the bit line BLi serves as a source region and the impurity diffusion layer connected to the bit line BLi+1 serves as a drain region. The potential difference Vdr is applied between the source and drain of the cell A2. If data is written to the cell A2, no current flows between the source and drain of the cell A2. If the cell A2 is in an erase state, current flows between the source and drain of the cell A2. The sense amplifier senses whether current is present or absent in the bit line BLi+1 (whether the potential of the bit line BLi+1 varies or not), thereby reading data from the cell A2.

In order to read data from the cell B1, the potential Vgr has only to be applied to only the control gate line CGj+1 and the other control gate lines CG1 to CGj and CGj+2 to CGn have only to be set at the ground potential GND when data is read out of the cell A1. Thus, data is read from the cell B1 as described above with respect to the read of data from the cell A1. In this case, the bit line BLi−1 serves as a source line and the bit line BLi serves as a drain line as in the operation of reading data from the cell A1.

In order to read data from the cell B2, the potential Vgr has only to be applied to only the control gate line CGj+1 and the other control gate lines CG1 to CGj and CGj+2 to CGn have only to be set at the ground potential GND when data is read out of the cell A2. Thus, data is read from the cell B2 as described above with respect to the read of data from the cell A2. In this case, the bit line BLi−1 serves as a source line and the bit line BLi+1 serves as a drain line as in the operation of reading data from the cell A2.

[Erase Operation]

The erase operation of the NOR EEPROM according to the second embodiment is similar to that of the prior art EEPROM.

In the foregoing NOR EEPROM according to the second embodiment, one of source and drain of memory cells in adjacent two columns is connected to a common bit line and the other is connected to a different bit line. The memory cells of two columns, which are connected to a common bit line BLi, are connected to bit lines BLi−1 and BLi+1. The memory cells of two columns, which are connected to a common bit line BLi−1, are connected to bit lines BLi and BLi−2. Further, the memory cells of two columns, which are connected to a common bit line BLi+1, are connected to bit lines BLi and BLi+2. As in the first embodiment, therefore, four memory cells have one bit line contact plug in common. The number of contact plugs can be reduced by half. The NOR EEPROM can thus be increased in packing density further. Furthermore, the cross-sectional area of the contact plug can be made larger than that of the prior art EEPROM. Consequently, the contact resistance at the contact plug can be lowered and accordingly the electrical characteristics of the NOR EEPROM can be improved.

The impurity diffusion layers of the memory cells MC included in the NOR EEPROM according to the second embodiment are connected to the bit lines BL, not the source or drain lines. In other words, the impurity diffusion layers of the memory cells MC are not divided into source and drain regions. The bit line BL alternately serves as a source line and a drain line in accordance with a selected memory cell MC. As has been described with reference to FIGS. 6A and 6B and FIGS. 8A and 8B, the bit line BLi serves as a drain line if the bit line BLi−1 serves as a source line when a memory cell connected to the bit lines BLi−1 and BLi is selected. In contrast, the bit line BLi serves as a source line if a memory cell connected to the bit lines BLi and BLi+1 is selected. Needless to say, when a memory cell connected to the bit lines BLi−1 and BLi is selected, the bit line BL can serves as a source line if the bit line BLi−1 can serves as a drain line.

Since both source and drain lines need not be used as described above, one column selector is sufficient for the second embodiment though two column selectors are required in the first embodiment. In other words, the source line SL and drain line DL can have one column selector in common. Furthermore, the voltage generation circuit 60 of the first embodiment exclusively for the source line SL becomes unnecessary. Thus, the circuit arrangement of the second embodiment can be simplified more greatly than that of the first embodiment, and the NOR EEPROM can be downsized.

As described above, according to the first and second embodiments of the present invention, adjacent four memory cells in the row and column directions have one of impurity diffusion layers in common. The number of contact plugs can thus be reduced by half. Therefore, the NOR EEPROM can be increased in packing density further. Furthermore, the cross-sectional area of the contact plug can be made larger than that of the prior art EEPROM. Consequently, the contact resistance at the contact plug can be lowered and accordingly the electrical characteristics of the NOR EEPROM can be improved.

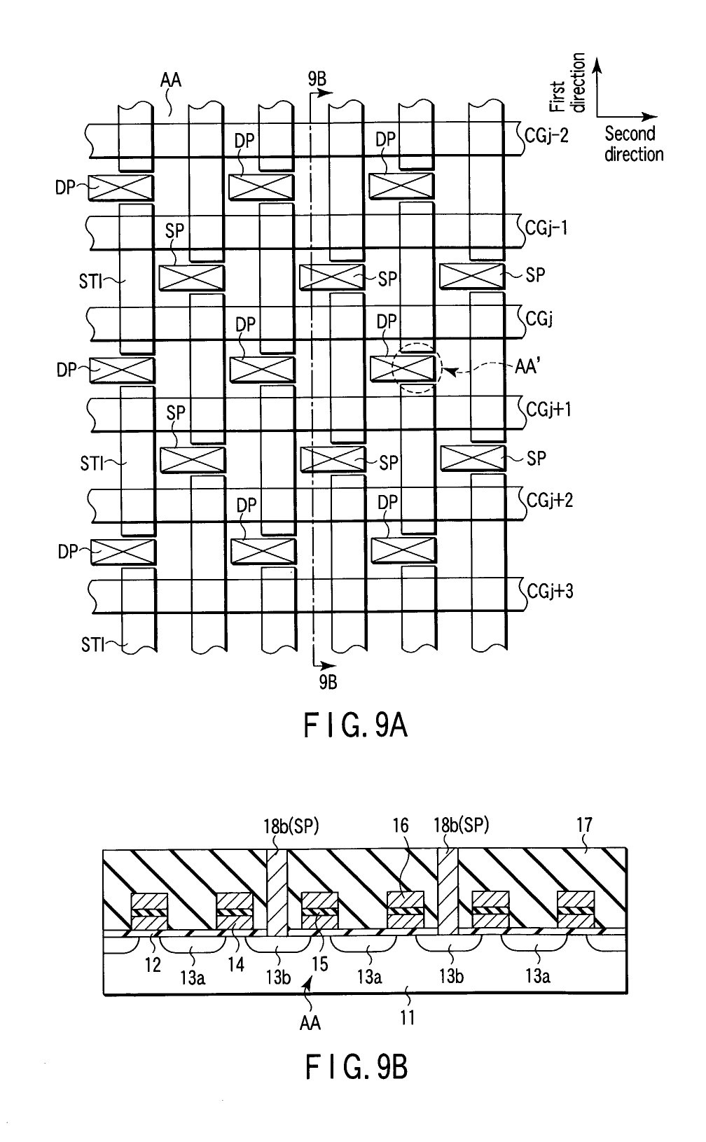

FIG. 9A is a plan view of a NOR EEPROM according to a first modification to the first and second embodiments of the present invention. FIG. 9B is a cross-sectional view taken along line 9B-9B of FIG. 9A. Neither source line SL nor drain line DL is shown.

Referring to FIG. 9A, a source contact plug SP and a drain contact plug DP are formed so as to reach the source and drain regions not only in an element region AA′ but also in one of its adjacent element regions AA. The cross-sectional area of the source contact plug SP and drain contact plug DP is larger than that in the first and second embodiments. In the first modification shown in FIG. 9A, the cross-sectional area is about twice as large as that in the first and second embodiments. Consequently, the source contact plug SP and drain contact plug DP can be decreased in resistance. Moreover, the contact area of the source contact plug SP and drain contact plug DP and the source and drain regions increases, with the result that the contact resistance can be lowered. The electrical characteristics of the NOR EEPROM can be improved.

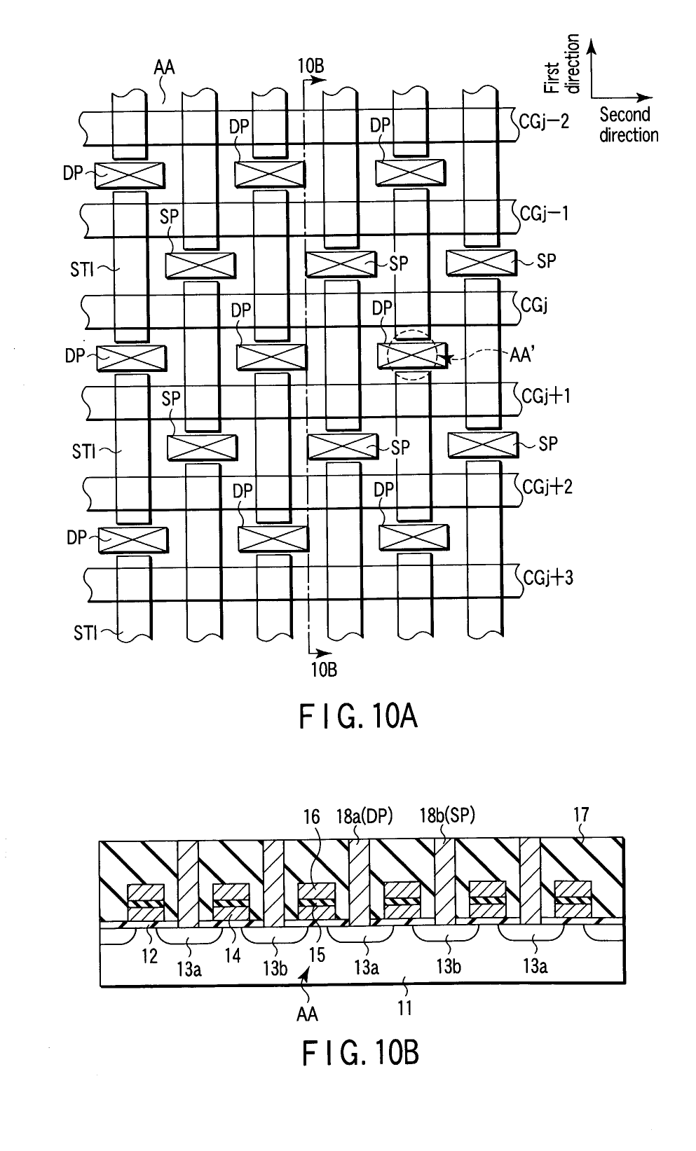

FIG. 10A is a plan view of a NOR EEPROM according to a second modification to the first and second embodiments of the present invention. FIG. 10B is a cross-sectional view taken along line 10B-10B of FIG. 10A. Neither source line SL nor drain line DL is shown.

Referring to FIG. 10A, a source contact plug SP and a drain contact plug DP are formed so as to reach the source and drain regions not only in an element region AA′ but also in its adjacent two element regions AA. The same advantage as that of the above first modification can be obtained from the second modification.

In the second modification, each of the contact plugs SP and DP can be provided in contact with its adjacent element isolation region ST1 in the row direction. In other words, each of the contact plugs can be expanded in the lateral direction as much as possible. In this case, the cross-sectional area of each of the contact plugs is about three times as large as that in the first and second embodiment and thus the contact resistance can be lowered further.

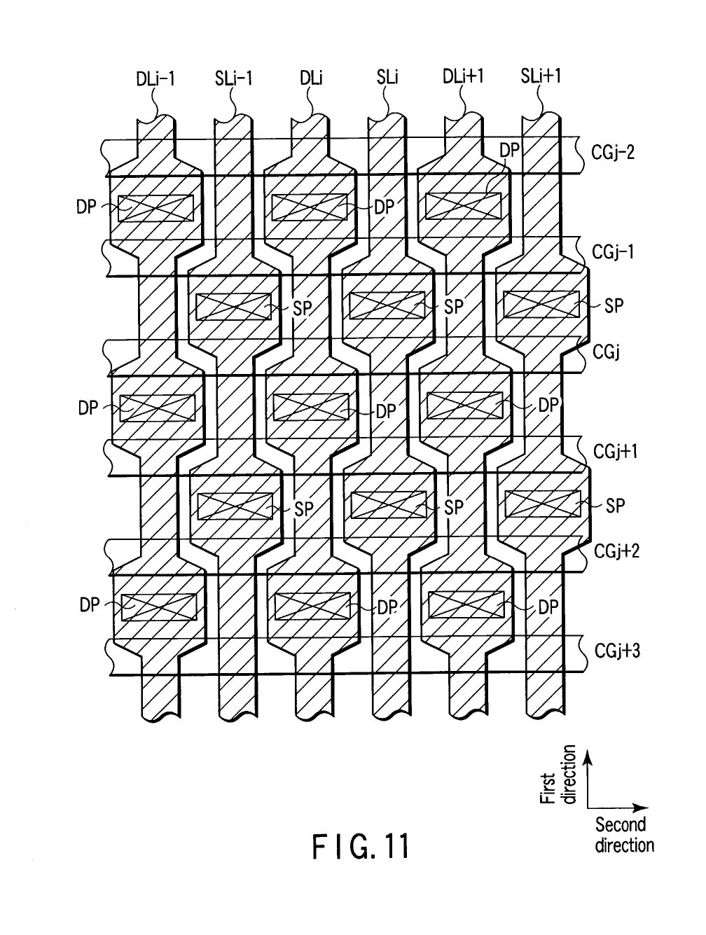

FIG. 11 is a plan view of a NOR EEPROM according to a third modification to the first and second embodiments of the present invention. No element isolation regions ST1 are shown. FIG. 11 shows a plane pattern of source and drain lines SL and DL of the first and second modifications. As shown, a portion with a contact plug and a portion without a contact plug are alternated with each other in the row direction in adjacent control gate lines. Therefore, the source and drain lines SL and DL can be broadened in regions where they are connected to the contact plugs and narrowed in the other regions. Using such a pattern, the top surfaces of the contact plugs can completely be covered with a metal wiring layer and the drain and source lines DL and SL can be formed by a metal wiring layer of the same level. Needless to say, the source and drain lines SL and DL can be formed by a metal wiring layer of a different level.

In the foregoing first to third modifications, too, both source and drain regions need not be formed. In other words, the bit lines can be used in place of the source and drain lines.

The embodiments of the present invention have been described, taking a NOR EEPROM as an example throughout the first and second embodiments and the first to third modifications thereto; however, it is not limited to the NOR EEPROM. For example, the embodiment of the present invention can be applied to a NAND EEPROM or a semiconductor memory other than the EEPROM.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory device comprising:
memory cells arranged in matrix, adjacent memory cells in a column direction having one of a source and a drain in common;
source lines to each of which sources of memory cells of adjacent two columns are connected;
drain lines to each of which drains of memory cells of adjacent two columns are connected, drains of memory cells of two columns connected to the source line being connected to different drain lines, respectively; and
a control gate line to which gates of adjacent memory cells in a row direction are connected.

2. The semiconductor memory device according to claim 1, further comprising a write circuit which applies a write potential and a ground potential to a drain line and a source line, respectively, which are connected to memory cells including a selected memory cell, and applies a potential, which causes the memory cells to be set at a same source-to-drain potential, to other drain and source lines, when data is written to the memory cells.

3. The semiconductor memory device according to claim 1, further comprising a read circuit which applies a read potential and a ground potential to a drain line and a source line, respectively, which are connected to memory cells including a selected memory cell, and applies a potential, which causes the memory cells to be set at a same source-to-drain potential, to other drain and source lines and senses a potential of the drain line connected to the selected memory cell, when data is read out of the memory cells.

4. The semiconductor memory device according to claim 1, further comprising:
an element isolation region which is formed between columns of the memory cells to electrically isolate the columns of the memory cells, and is partly removed such that sources of two memory cells arranged adjacent in the row direction and having a source line in common are connected to each other and drains of two memory cells arranged adjacent in the row direction and having a source line in common are connected to each other,;
a source contact plug which connects the sources of the memory cells and the source line, and is formed in spaces corresponding to removed element isolation regions; and
a drain contact plug which connects the drains of the memory cells and the drain line, and is formed in spaces corresponding to removed element isolation regions.

5. A semiconductor memory device comprising:
memory cells arranged in matrix, adjacent memory cells in a column direction having one of one end and other end of a current path in common;
bit lines to each of which one end of each of current paths of memory cells in adjacent two columns or other end thereof is connected, the other ends of the current paths of the memory cells being connected to different bit lines when the one end of each of the current paths of the memory cells is connected to a common one of the bit lines; and
control gate lines to each of which gates of adjacent memory cells in a row direction are connected.

6. The semiconductor memory device according to claim 5, further comprising a write circuit which applies a write potential and a ground potential to one and other of bit lines connected to memory cells including a selected memory cell, and applies a potential, which causes both ends of the current paths of the memory cells to be set at a same potential, to other bit lines, when data is written to the memory cells.

7. The semiconductor memory device according to claim 5, further comprising a read circuit which applies a read potential and a ground potential to one and other of bit lines connected to memory cells including a selected memory cell, and applies a potential, which causes both ends of the current paths of the memory cells to be set at a same potential, to other bit lines and senses a potential of one of bit lines connected to the selected memory cell, when data is read out of the memory cells.

8. The semiconductor memory device according to claim 5, further comprising:
an element isolation region which is formed between columns of the memory cells to electrically isolate the columns of the memory cells, and is partly removed such that one end of a current path of one of adjacent two memory cells in the row direction and having a bit line in common is connected to one end of a current path of other memory cell and other ends of the current paths of the two memory cells are connected to each other and;
a bit line contact plug which connects the one end of the current path and the other end thereof to bit lines, respectively, and is formed in a space corresponding to a removed element isolation region.

9. A semiconductor memory device comprising:
a memory cell array including a plurality of first memory cell units arranged in matrix, each of the first memory cell units having four memory cells arrange in matrix, the four memory cells having current paths whose ends are connected to one another;
second memory cell units each including four memory cells, the four memory cells corresponding to closest four memory cells of adjacent four first memory cell units, other ends of current paths of the closest four memory cells being connected to one another;
a first wire which connects ends of current paths of first memory cell units in same column;
a second wire which connects other ends of current paths of second memory cell units in same column; and
a control gate line which connects gates of memory cells in same row.

10. The semiconductor memory device according to claim 9, further comprising write and read circuits which cause a potential difference only between first and second wires connected to a selected memory cell when data is written to and read from a memory cell.

11. The semiconductor memory device according to claim 9, further comprising:
first element isolation regions each of which is formed between adjacent first memory cell units in a row direction to electrically isolate the adjacent first memory cell units;
second element isolation regions each of which is formed between adjacent second memory cell units in the row direction to electrically isolate the adjacent second memory cell units;
a first contact plug which is formed between adjacent second element isolation regions in a column direction to connect a common one end of the current paths in each of the first memory cell units to the first wire; and
a second contact plug which is formed between adjacent first element isolation regions in the column direction to connect a common other end of the current paths in each of the second memory cell units to the second wire.

12. The semiconductor memory device according to claim 1, wherein each of the memory cells is a nonvolatile flash cell having a multilayer gate structure including a control gate electrode and a floating gate electrode.

13. The semiconductor memory device according to claim 5, wherein each of the memory cells is a nonvolatile flash cell comprising a multilayer gate structure including a control gate electrode and a floating gate electrode.

14. The semiconductor memory device according to claim 9, wherein each of the memory cells is a nonvolatile flash cell comprising a multilayer gate structure including a control gate electrode and a floating gate electrode.

15. A semiconductor memory device comprising:
element isolation regions arranged in a staggered format in a semiconductor substrate, a longitudinal direction of the element isolation regions being equal to a first direction;
a plurality of control gate lines formed on the semiconductor substrate along a second direction perpendicular to the first direction, two control gate lines passing across each of the element isolation regions, and an n-th (n is natural number larger than one) control gate line alternately passing across same element isolation regions as those across which (n+1)-th and (n−1)-th control gate lines pass; and
a contact region formed between adjacent element isolation regions in the first direction.

16. The semiconductor memory device according to claim 15, further comprising:
first source and drain regions formed alternately in a surface area of the semiconductor substrate, each of the control gate lines being interposed between the first source and drain regions;
a second source region formed in the contact region located in the first source region interposed between the control gate lines, the second source region being connected to the first source region;
a second drain region formed in the contact region located in the first drain region interposed between the control gate lines, the second drain region being connected to the first drain region;
source and drain contact plugs formed on the second source and drain regions, respectively; and
source and drain lines formed along the first direction, the source and drain lines connecting source and drain contact plugs formed in the first direction.

17. The semiconductor memory device according to claim 16, wherein the source and drain contact plugs are formed in contact with first drain and source regions, respectively, which are arranged adjacent to the contact region in the second direction.

18. The semiconductor memory device according to claim 15, further comprising:
a first impurity diffusion layer formed in a surface area of the semiconductor substrate between the control gate lines;
a second impurity diffusion layer formed in the contact region in contact with the first impurity diffusion layer;
a bit line contact plug formed on the second impurity diffusion layer; and
a bit line formed along the first direction so as to connect adjacent bit line contact plugs in the first direction.

19. The semiconductor memory device according to claim 18, wherein the bit line contact plug is formed in contact with a first impurity diffusion layer which is arranged adjacent to the contact region in the second direction.
